(19) United States
(12) Patent Application Publication
(10) Pub. No.: US 2006/0011578 A1
(43) Pub. Date: Jan. 19, 2006

(54) Low-k dielectric etch

(75) Inventors: Sean S. Kang, Fremont, CA (US); Zhisong Huang, Fremont, CA (US); S. M. Reza Sadjadi, Saratoga, CA (US)

Correspondence Address: BEYER WEAVER & THOMAS LLP, P.O. BOX 70250, OAKLAND, CA, 94612-0250, US

(73) Assignee: Lam Research Corporation

(21) Appl. No.: 10/892,945

(22) Filed: Jul. 16, 2004

(51) Int. Cl. H01L 21/302; B44C 1/22

(52) U.S. Cl. 216/67; 216/41; 216/58; 438/710; 156/345.35

(57) ABSTRACT

A method for etching a dielectric layer below a photoresist mask is provided. A wafer with the dielectric layer disposed below a photoresist mask is provided in an etch chamber. An etch gas comprising CF₄ and H₂ is provided into the etch chamber wherein the CF₄ has a flow rate and the H₂ has a flow rate, wherein the flow rate of H₂ is greater than the flow rate of CF₄. A plasma is formed from the etch gas. Features are etched into the dielectric layer through the etch mask using the plasma formed from the etch gas.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer.

Various generations of photoresist are known. 193 nm photoresist and 157 nm photoresist and smaller generation photoresist are desired to provide smaller device sizes and increased device density. 193 nm and 157 nm photoresist may be softer than previous generation photoresist and may be more like polymer and especially, low-k dielectric polymer, which would decrease the selectivity of an etch of a low-k dielectric with respect to the photoresist.

### SUMMARY OF THE INVENTION

To achieve the foregoing and in accordance with the purpose of the present invention a method for etching a dielectric layer below a photoresist mask is provided. A wafer with the dielectric layer disposed below a photoresist mask is provided in an etch chamber. An etch gas comprising CF₄ and H₂ is provided into the etch chamber wherein the CF₄ has a flow rate and the H₂ has a flow rate, wherein the flow rate of H₂ is greater than the flow rate of CF₄. A plasma is formed from the etch gas. Features are etched into the dielectric layer through the etch mask using the plasma formed from the etch gas.

In another manifestation of the invention, a method for etching an etch layer below an organic material mask is provided. A wafer with the etch layer disposed below the organic material mask is provided in an etch chamber. An etch gas comprising CF₄ and H₂ is provided into the etch chamber wherein the CF₄ has a flow rate and the H₂ has a flow rate, wherein the flow rate of H₂ is greater than the flow rate of CF₄. A plasma is formed from the etch gas. Features are etched into the etch layer through the organic material mask using the plasma formed from the etch gas.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIGS. 2A-C are cross sectional view of a wafer during various steps of the inventive process.

FIG. 3 is a schematic view of a plasma processing chamber 300 that may be used for depositing the layer, etching, and stripping that may be used by the invention.

FIGS. 4A and 4B illustrate a computer system, which is suitable for implementing a controller used in embodiments of the present invention.

FIGS. 5A and 5B are photographs of cross-sections of layers etched using the inventive etch.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The invention provides an etch process that is able selectively etch a dielectric layer, especially a low-k dielectric layer, with respect to a 197 nm or smaller generation photoresist with a high selectivity. The selectivity may approach infinity.

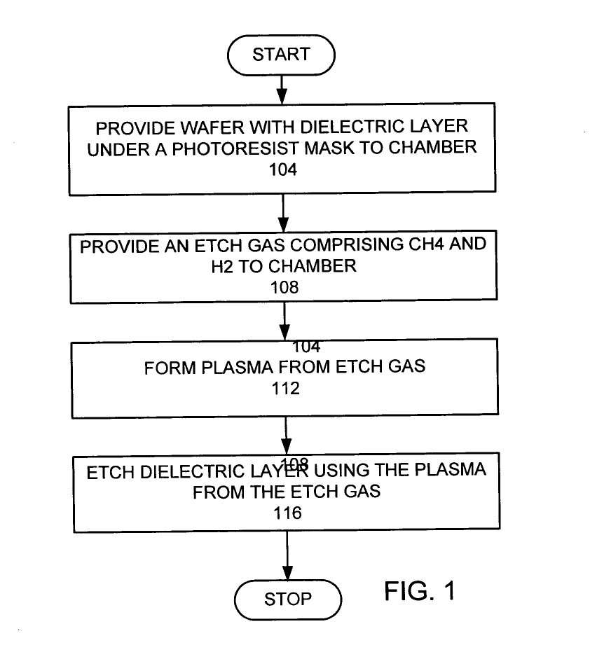

To facilitate understanding, FIG. 1 is a high level flow chart of a process that may be used in an embodiment of the invention. A wafer with a dielectric layer disposed under a photoresist mask is placed into a process chamber (step 104). An etch gas comprising CH₄ and H₂ is provided to the etch chamber (step 108). The etch gas has a H₂ flow rate that is greater than the flow rate of the CF₄ of the etch gas. A plasma is formed from the etch gas (step 112). Features are etched into the dielectric layer through the etch mask using the plasma from the etch gas (step 116).

### EXAMPLE

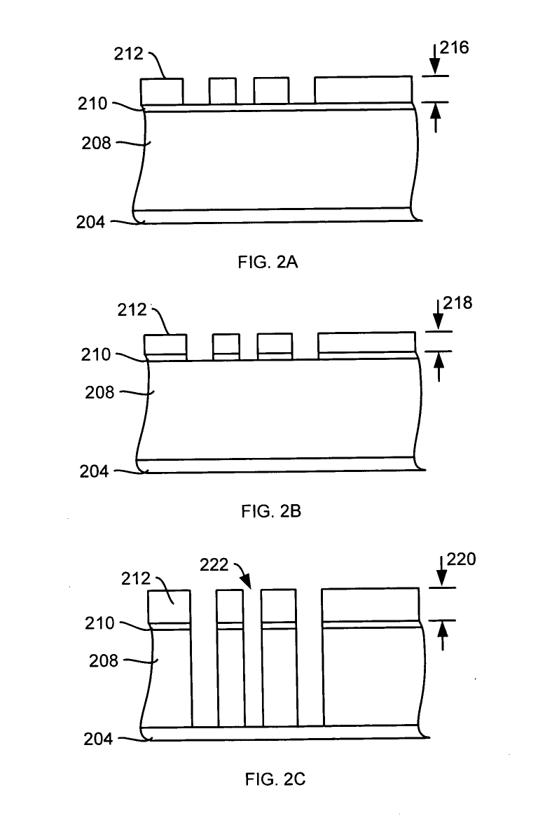

In an example of the inventive process for forming a trench, a wafer with a dielectric layer disposed under a photoresist mask is placed into a process chamber (step 104). In an example of the invention, FIG. 2A is a cross sectional view of a wafer 204 with a dielectric layer 208, disposed below a bottom antireflective coating (BARC) 210, disposed below a photoresist mask 212. Preferably, the dielectric layer 208 is a low-k dielectric, which has a k<3.0. In addition, the photoresist that forms the photoresist mask 212 is a 193 nm or less generation photoresist, so that the photoresist is not greater than a 193 nm generation photoresist. Because of the high selectivity of the inventive etch the photoresist mask may have an applied thickness 216 of less than 3000 Å. In this example, the low-k dielectric material is an organosilicate glass, such as Coral, Black Diamond, or Aurora.

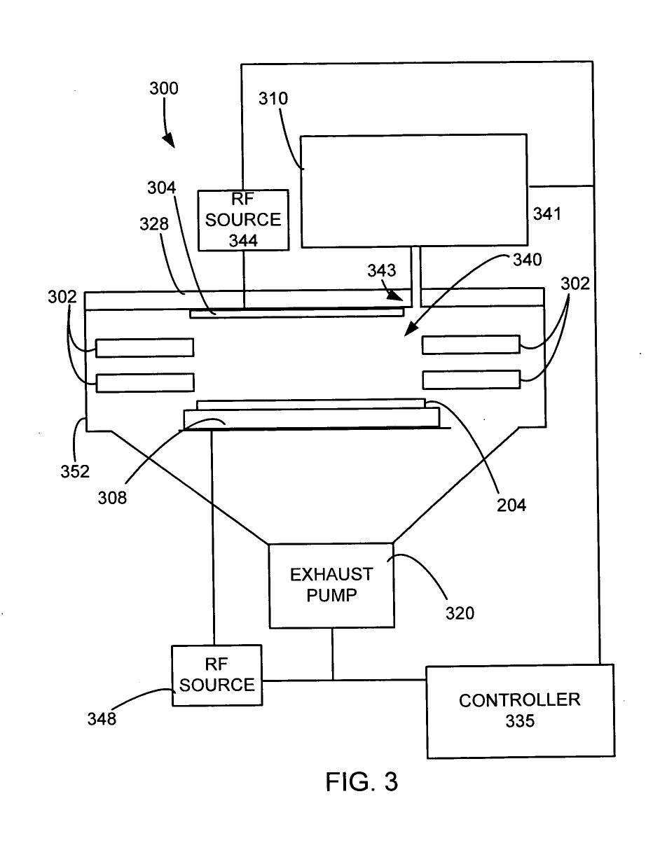

FIG. 3 is a schematic view of a plasma processing chamber 300 that may be used for depositing the layer, etching, and stripping that may be used in this example. The plasma processing chamber 300 comprises confinement rings 302, an upper electrode 304, a lower electrode 308, a gas source 310, and an exhaust pump 320. Within plasma processing chamber 300, the wafer 204 is positioned upon the lower electrode 308. The lower electrode 308 incorporates a suitable substrate chucking mechanism (e.g., electrostatic, mechanical clamping, or the like) for holding the wafer 204. The reactor top 328 incorporates the upper electrode 304 disposed immediately opposite the lower electrode 308. The upper electrode 304, lower electrode 308, and confinement rings 302 define the confined plasma volume. Gas is supplied to the confined plasma volume by the gas source 310 and is exhausted from the confined plasma volume through the confinement rings 302 and an exhaust port by the exhaust pump 320. A first RF source 344 is electrically connected to the upper electrode 304. A second RF source 348 is electrically connected to the lower electrode 308. Chamber walls 352 surround the confinement rings 302, the upper electrode 304, and the lower electrode 308. Both the first RF source 344 and the second RF source 348 may comprise a 27 MHz power source and a 2 MHz power source. Different combinations of connecting RF power to the electrode are possible. In the case of a 2300 Flex™ or a Exelan HPT or a 2300™ Exelan, made by LAM Research Corporation™ of Fremont, Calif., which may be used in a preferred embodiment of the invention, both the 27 MHz and 2 MHz power sources make up the second RF power source 348 connected to the lower electrode, and the upper electrode is grounded. A controller 335 is controllably connected to the RF sources 344, 348, exhaust pump 320, and the gas source 310.

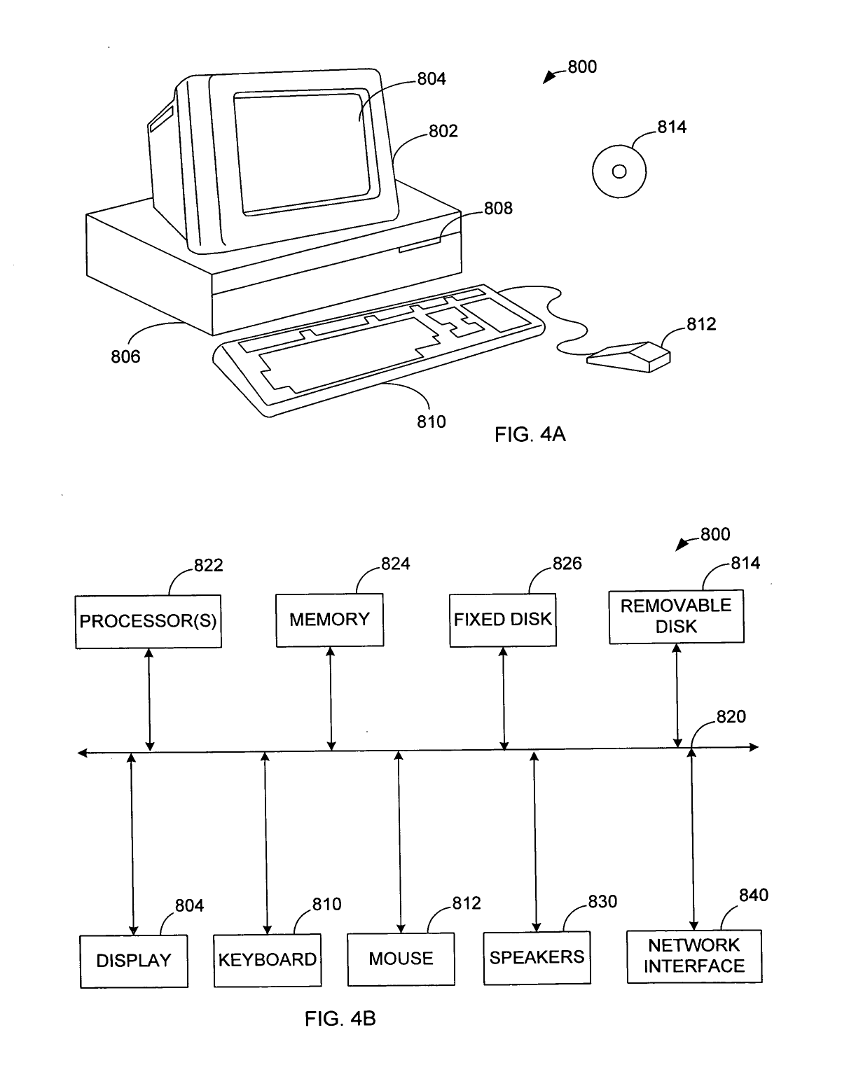

FIGS. 4A and 4B illustrate a computer system 800, which is suitable for implementing a controller 335 used in embodiments of the present invention. FIG. 4A shows one possible physical form of the computer system. Of course, the computer system may have many physical forms ranging from an integrated circuit, a printed circuit board, and a small handheld device up to a huge super computer. Computer system 800 includes a monitor 802, a display 804, a housing 806, a disk drive 808, a keyboard 810, and a mouse 812. Disk 814 is a computer-readable medium used to transfer data to and from computer system 800.

FIG. 4B is an example of a block diagram for computer system 800. Attached to system bus 820 is a wide variety of subsystems. Processor(s) 822 (also referred to as central processing units, or CPUs) are coupled to storage devices, including memory 824. Memory 824 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 826 is also coupled bi-directionally to CPU 822; it provides additional data storage capacity and may also include any of the computer-readable media described below. Fixed disk 826 may be used to store programs, data, and the like and is typically a secondary storage medium (such as a hard disk) that is slower than primary storage. It will be appreciated that the information retained within fixed disk 826 may, in appropriate cases, be incorporated in standard fashion as virtual memory in memory 824. Removable disk 814 may take the form of any of the computer-readable media described below.

CPU 822 is also coupled to a variety of input/output devices, such as display 804, keyboard 810, mouse 812 and speakers 830. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 822 optionally may be coupled to another computer or telecommunications network using network interface 840. With such a network interface, it is contemplated that the CPU might receive information from the network, or might output information to the network in the course of performing the above-described method steps. Furthermore, method embodiments of the present invention may execute solely upon CPU 822 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

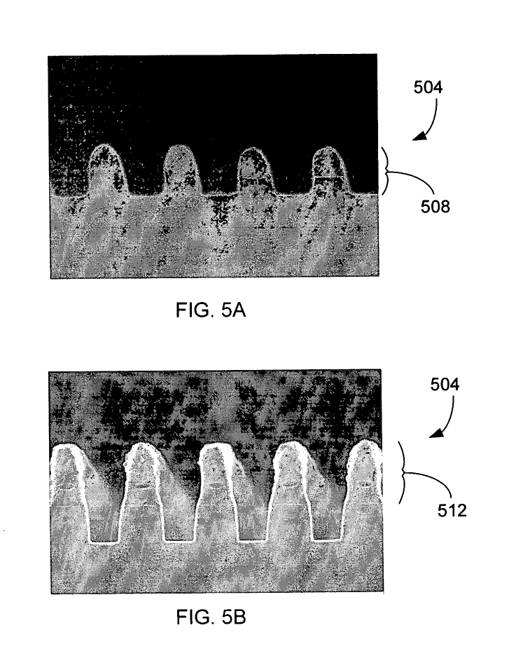

In this example, the bottom antireflective coating (BARC) 210 is opened before the etching of the dielectric layer. The opening of the BARC 210 reduces the thickness of the photoresist mask to a remaining photoresist mask thickness 218, as shown in FIG. 2B. The photoresist mask may have a remaining mask thickness of less than 2000 Å. In this example, the BARC opening is through a process where a pressure of 100 mTorr is maintained in the chamber 300. 200 watts at 27 MHz and 0 watts at 2 MHz of power is provided. A BARC open gas of 100 sccm CF₄ is provided. The BARC open process is maintained for 49 seconds. FIG. 5A is a photograph of a cross-sectional view of a dielectric layer disposed below a photoresist mask and a BARC layer 504 after the BARC has been opened and before the main etch. The photoresist and BARC have a photoresist and BARC thickness 508 of about 182 nm.

Next an etch gas comprising CF₄ and H₂ is provided from the gas source 310 (step 108). In this example, the etch gas provides a flow of 60 sccm CF₄, 70 sccm H₂, and 300 sccm Ar. A plasma is generated from the etch gas (step 112). In this example, the chamber pressure is maintained at 80 mTorr. 600 watts are provided at 27 MHz and 200 watts are provided at 2 MHz. The plasma formed from the etch gas is used to etch features in the dielectric layer 208 (step 116). This process is maintained for 60 seconds to etch a 2681 Å feature depth. This example provides no loss of photoresist, but instead adds polymer to the photoresist, while etching features in the dielectric layer, which thus provides a dielectric to photoresist etch selectivity of infinity. FIG. 2C is a cross-sectional view of the wafer 204 after the etching of features 222 in the dielectric layer 208 is completed. It should be noted that the thickness 220 of the combined remaining photoresist mask and polymer added during the etch is greater than the remaining photoresist mask thickness 218 before etching. FIG. 5B is a photograph of a cross-sectional view of a dielectric layer disposed below a photoresist mask and a BARC layer 504 after the main etch, using the above etch parameters. The photoresist and BARC have a photoresist and BARC thickness 512 of about 229 nm. So, the added polymer has increased the thickness of the photoresist during the etching process.

The photoresist mask is then stripped.

Such an inventive process may be used to provide infinite selectivity. The inventive process is able to add to the thickness of the photoresist, while etching.

In other embodiments of the invention, other organic layers may be used as an etch mask instead of 193 nm or higher generation photoresist masks. It has been found that the remaining organic layer before the etch may be less than 2000 Å. More preferably, the remaining organic or photoresist layer before the etch is less than 1000 Å. Most preferably the remaining organic or photoresist layer before the etch is less than 500 Å. By allowing the use of thinner photoresist masks of higher generation photoresists, the critical dimensions can be decreased, since thinner photoresist masks of higher generation photoresist provide higher resolution.

It is preferred that the flow rate of H₂ be greater than the flow rate of CF₄. It is more preferable that the flow rate of H₂ (x) be greater than the flow rate of CF₄ (y) and less than five times the flow rate of CF₄ (5y), so that 5y>x>y. It is more preferable that the flow rate of H₂ (x) be either between five times the flow rate of CF₄ (5y) and three times the flow rate of CF₄ (3y) or two times the flow rate of CF₄ (2y) and the flow rate of CF₄ (y), such that 5y>x>3y or 2y>x>y.

For a flow rate of 60 sccm CF₄, it is preferred that the flow rate of H₂ would be between 60 sccm and 120 sccm providing an H₂ to CF₄ flow ratio of between about 1:1 to 2:1. The most preferable flow rate is 80 sccm H₂. For a flow rate of 35 sccm CF₄, it is preferable that the flow rate of H₂ would be between 100 to 175 sccm H₂, providing an H₂ to CF₄ flow ratio between about 3:1 to 5:1. The other most preferred flow rate is 120 sccm H₂.

For etching a low-k dielectric, the above recipes may be used with the addition of N₂ gas. A preferred flow rate for N₂ that may be added to the above recipes is 5 sccm to 40 sccm N₂. A most preferred flow rate is about 20 sccm N₂.

In an example of a recipe that uses N₂, during a main etch a pressure of 90 mTorr is maintained in the chamber. An etching gas consisting essentially of 40 sccm CF₄, 50 sccm H₂, 20 sccm N₂, and 100 sccm Ar is provided into the chamber. 800 Watts are provided at 27 MHz. 400 Watts are provided at 2 MHz. This recipe provided an etch where the thickness of the mask increased, and in addition no striation (sidewall polymer deposition) was found, and where the feature had a very vertical profile.

It is preferred that the power ranges for the higher frequency power source (i.e. 27 MHz power source) be between 200 W˜1500 W and for the lower frequency power source (i.e. 2 MHz power source) be from 0 W˜1000 W. It is more preferred that the power ranges for the higher frequency power source be between 500 W˜1200 W and for the lower frequency power source be between 200 W˜800 W. It is most preferred that the power ranges for the higher frequency power source be between 800 W˜1000 W and for the lower frequency power source be between 300 W˜600 W. Another example of a recipe that uses the above power rages for etching a low-k via provides a pressure of 90 mTorr, with a high frequency power of 1000 W and a lower frequency power of 400 W.

Without being bound by theory, it is believed that CF₄ is a strong etchant providing four fluorine atoms for etching for each carbon atom. As a result, H₂ is added to protect the photoresist. It was believed that such a combination would cause etch stop. It was unexpectedly found that such a combination does not cause etch stop.

In other embodiments N₂ may be added to the etch gas at a flow rate of between 5-40 sccm, when a low-k dielectric is being etched. It is believed that N₂ provides a leaner etch gas that scavenges carbon during a low-k dielectric etch for organosilicate glass (OSG), such as Coral (manufactured by Novellus of San Jose, Calif., Black Diamond manufactured by Applied Materials Inc. of Santa Clara, Calif.), and Aurora (manufactured by ASM Japan KK of Tokyo), which results in the formation of less polymer.

It has been found that the inventive process provides etching rates of over 1 micron per minute. The inventive etch process has been found to provide an etch of up to about 1.3 microns per minute. Even higher etch rates may be achieved with higher powers.

Too fast an etch rate may be too hard to control. Argon may be added to slow down etch rates. This allows for greater control of etch rates by controlling the flow of argon.

It is preferred that the etch time using the inventive etch gas is greater than 10 seconds. It is more preferred that the etch time is greater than 20 seconds.

It has been unexpectedly found that the inventive process reduces striation. It is believed that striation is reduced because this process not only deposits on PR but also deposits a thin layer of sidewall polymer. This sidewall polymer is believed to reduce the formation of striation.

The invention may be used for various applications, such as in the formation of vias, formation of trenches, and the opening of silicon nitride hard mask. The hard mask may be above a low-k dielectric. The inventive process would then allow a thin photoresist mask to be used for both opening the hard mask and etching the dielectric layer, especially low-k dielectric layers.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for etching a dielectric layer below a photoresist mask, comprising:
providing a wafer with the dielectric layer disposed below a photoresist mask into an etch chamber;
providing an etch gas comprising CF₄ and H₂ into the etch chamber wherein the CF₄ has a flow rate and the H₂ has a flow rate, wherein the flow rate of H₂ is greater than the flow rate of CF₄;
forming a plasma from the etch gas; and
etching features into the dielectric layer through the etch mask using the plasma formed from the etch gas.

2. The method, as recited in claim 1, wherein the photoresist mask has a thickness of less than 2000 Å before etching the feature.

3. The method, as recited in claim 2, the photoresist is not greater than a 193 nm generation photoresist.

4. The method, as recited in claim 3, wherein the etching features into the dielectric layer adds polymer on the photoresist mask during the etching so that a thickness of the mask increases to provide infinite etch selectivity for etching the dielectric layer with respect to the photoresist mask.

5. The method, as recited in claim 4, wherein the flow rate of the H₂ is less than five times the flow rate of CF₄.

6. The method, as recited in claim 5, wherein the photoresist mask has a thickness of less than 500 Å before etching the feature.

7. The method, as recited in claim 6, wherein the flow rate of H₂ is greater than three times the flow rate of CF₄.

8. The method, as recited in claim 7, wherein the etch gas further comprises N₂.

9. The method, as recited in claim 8, wherein the dielectric layer is a low-k dielectric layer.

10. The method, as recited in claim 9, wherein the N₂ has a flow rate between 5-40 sccm.

11. The method, as recited in claim 10, wherein the etching provides an etch rate greater than 1 micron per minute.

12. The method, as recited in claim 10, wherein the etch gas further comprises argon.

13. The method, as recited in claim 12, wherein the etching the feature is performed for more than 20 seconds.

14. The method, as recited in claim 1, wherein the flow rate of H₂ is less than two times the flow rate of CF₄.

15. The method, as recited in claim 1, wherein the etching features into the dielectric layer further deposits polymer on sidewalls of the features, which reduces striation.

16. The method, as recited in claim 1, the photoresist is not greater than a 193 nm generation photoresist.

17. The method, as recited in claim 1, wherein the etching features into the dielectric layer adds polymer on the photoresist mask during the etching so that a thickness of the mask increases to provide infinite etch selectivity for etching the dielectric layer with respect to the photoresist mask.

18. The method, as recited in claim 1, wherein the flow rate of the H₂ is less than five times the flow rate of CF₄.

19. The method, as recited in claim 1, wherein the photoresist mask has a thickness of less than 500 Å before etching the feature.

20. The method, as recited in claim 1, wherein the flow rate of H₂ is greater than three times the flow rate of CF₄.

21. The method, as recited in claim 1, wherein the etch gas further comprises N₂.

22. The method, as recited in claim 21, wherein the dielectric layer is a low-k dielectric layer.

23. The method, as recited in claim 22, wherein the N₂ has a flow rate between 5-40 sccm.

24. A semiconductor device formed by the method of claim 1.

25. An apparatus for performing the method of claim 1.

26. A method for etching an etch layer below an organic material mask, comprising:
providing a wafer with the etch layer disposed below the organic material mask into an etch chamber;
providing an etch gas comprising CF₄ and H₂ into the etch chamber wherein the CF₄ has a flow rate and the H₂ has a flow rate, wherein the flow rate of H₂ is greater than the flow rate of CF₄;
forming a plasma from the etch gas; and
etching features into the etch layer through the organic material mask using the plasma formed from the etch gas.

27. The method, as recited in claim 26, wherein the organic material mask has a thickness of less than 2000 Å before etching the feature.

28. The method, as recited in claim 27, wherein the etching features into the etch layer adds polymer on the organic material mask during the etching so that a thickness of the mask increases to provide infinite etch selectivity for etching the etch layer with respect to the organic material mask.

29. The method, as recited in claim 28, wherein the flow rate of the H₂ is less than five times the flow rate of CF₄.

30. The method, as recited in claim 29, wherein the organic material mask has a thickness of less than 500 Å before etching the feature.

31. The method, as recited in claim 30, wherein the flow rate of H₂ is greater than three times the flow rate of CF₄.

32. The method, as recited in claim 31, wherein the etch gas further comprises N₂.

33. The method, as recited in claim 32, wherein the N₂ has a flow rate between 5-40 sccm.

34. The method, as recited in claim 33, wherein the dielectric layer is a low-k dielectric layer.

35. The method, as recited in claim 34, wherein the etching provides an etch rate greater than 1 micron per minute.

36. The method, as recited in claim 35, wherein the etching the feature is performed for more than 20 seconds.

37. The method, as recited in claim 26, wherein the flow rate of H₂ is less than two times the flow rate of CF₄.

38. The method, as recited in claim 26, wherein the etching features into the dielectric layer further deposits polymer on sidewalls of the features, which reduces striation.

39. The method, as recited in claim 26, wherein the etch gas further comprises N₂.

40. The method, as recited in claim 39, wherein the dielectric layer is a low-k dielectric layer.

41. The method, as recited in claim 40, wherein the N₂ has a flow rate between 5-40 sccm.
